(19) United States
(12) Patent Application Publication
(10) Pub. No.: US 2025/0331344 A1
(43) Pub. Date: Oct. 23, 2025

(54) LIGHT EMITTING DIODE PIXEL PACKAGE AND MANUFACTURING METHOD FOR LIGHT EMITTING DIODE PIXEL PACKAGE

(71) Applicant: INGENTEC CORPORATION, Miaoli County (TW)

(72) Inventors: Chia-Pin WANG, Miaoli County (TW); Ai-Sen LIU, Miaoli County (TW); Hsiang-An FENG, Miaoli County (TW)

(21) Appl. No.: 18/920,963

(22) Filed: Oct. 20, 2024

(30) Foreign Application Priority Data
Apr. 19, 2024 (TW) 113114747

(51) Int. Cl. H01L 33/62; H01L 25/16; H01L 33/56

(52) U.S. Cl. CPC H10H 20/857; H01L 25/167; H10H 20/854; H10H 20/0362; H10H 20/0364

(57) ABSTRACT

A light emitting diode pixel package includes a substrate, a driving circuit die, LED dice, electrode pads and a packaging glue layer. The substrate includes a front pixel area, a back pixel area and a recess. The driving circuit die is disposed at the recess and includes a die top surface. The LED dice are disposed at the front pixel area periodically, each the LED dice includes a light emitting surface, and each light emitting surface is higher than the die top surface. One end of the first transparent conducting pattern is connected to the driving circuit die, and another end of the first transparent conducting pattern is connected to the LED die. One end of the second transparent conducting pattern is connected to the driving circuit die, and another end of the second transparent conducting pattern is connected to the electrode pad.

### RELATED APPLICATIONS

This application claims priority to Taiwan Application Serial Number 113114747, filed Apr. 19, 2024, which is herein incorporated by reference.

### BACKGROUND

### Technical Field

The present disclosure relates to a package and a method for manufacturing the package. More particularly, the present disclosure relates to a light emitting diode pixel package and a manufacturing method for light emitting diode pixel packages.

### Description of Related Art

With the advance of technology, light emitting diodes (LED) become tiny to be applied to more products. For example, mini LEDs or micro LEDs are applied to displays. During manufacturing, a substrate, three LED dice and a driving IC may be packaged as a light emitting diode pixel package which can be used in future assembling and application.

However, the driving IC and the LED dice are generally disposed on a surface of the substrate, and then are electrically connected by wiring, which may lead to a difficulty for decreasing the size of the light emitting diode pixel package. Moreover, a top surface of the driving IC is higher than emitting surfaces of the LED dice, and the light will be blocked.

Hence, the structure of the light emitting diode pixel package is modifier. The LED dice are disposed on the top surface of the driving IC, then are electrically connected to the driving IC by wiring, and the light blocking problem and the size problem may be solved. However, the stocked structure may cause a problem that the heat of the LED dice is directly transferred to the driving IC during work, the elements may be damaged owning to overheat, and the stability and the life time may be affected. In addition, as the sizes of the LED die and the light emitting diode pixel package decrease, the difficulty of wiring increases. Furthermore, packaging after wiring may lead the light emitting diode pixel package to have a specific thickness, which does not facilitate for decreasing the thickness.

Based on the aforementioned problems, how to improve the structure of the light emitting diode pixel package to decrease the thickness and to prevent the light of the LED die from being blocked becomes a target that those in the filed pursue.

### SUMMARY

According to one aspect of the present disclosure, a light emitting diode pixel package includes a substrate, a driving circuit die, a plurality of LED dice, a plurality of electrode pads and a packaging glue layer. The substrate includes a front pixel area, a back pixel area opposite to the front pixel area, and a recess located at the front pixel area. The driving circuit die is disposed at the recess and includes a die top surface. The LED dice are disposed at the front pixel area periodically, each of the LED dice includes a light emitting surface, and each of the light emitting surfaces is higher than the die top surface. The electrode pads are disposed at the front pixel area periodically. The packaging glue layer is disposed at the front pixel area and includes a plurality of first transparent conducting patterns and a plurality of second transparent conducting patterns. One end of each of the first transparent conducting patterns is connected to the driving circuit die, and another end of each of the first transparent conducting patterns is connected to each of the LED dice. One end of each of the second transparent conducting patterns is connected to the driving circuit die, and another end of each of the second transparent conducting patterns is connected to each of the electrode pads.

According to another embodiment of the present disclosure, a manufacturing method for light emitting diode pixel packages includes an integrated circuit wafer providing step, a packaging glue coating step, a transparent conductive pattern forming step and a cutting step. In the integrated circuit wafer providing step, an integrated circuit wafer is provided. The integrated circuit wafer includes a substrate, a plurality of driving circuit dice, a plurality of LED die groups and a plurality of electrode pad groups. The substrate includes a plurality of front pixel areas and a plurality of recesses. Each of the recesses is located at each of the front pixel areas. Each of the driving circuit dice is disposed at each of the recesses and includes a die top surface. Each of the LED die groups is located at each of the front pixel areas. Each of the LED die groups includes a plurality of LED dice arranged periodically, and each of the LED dice includes a light emitting surface. Each of the light emitting surfaces is higher than each of the die top surfaces, and each of the electrode pad groups is located at each of the front pixel areas. In the packaging glue coating step, a packaging glue is coated on the front pixel areas of the substrate to cover the driving circuit dice, the LED die groups and the electrode pad groups. In the transparent conductive pattern forming step, a plurality of grooves are formed on the packaging glue, and a transparent conducting glue is covered thereon. The transparent conducting glue flows into the grooves to form a plurality of first transparent conducting pattern groups and a plurality of second transparent conducting pattern groups, and the first transparent conducting pattern groups, the second transparent conducting pattern groups and the transparent conducting glue forms a packaging glue layer. Each of the first transparent conducting pattern groups corresponds to each of the front pixel areas and includes a plurality of first transparent conducting patterns, one end of each of the first transparent conducting patterns of each of the first transparent conducting pattern groups is connected to the driving circuit die of each of the front pixel areas, and another end of each of the first transparent conducting patterns of each of the first transparent conducting pattern groups is connected to each of the LED dice of each of the front pixel areas. Each of the second transparent conducting pattern groups corresponds to each of the front pixel areas and includes a plurality of second transparent conducting patterns, one end of each of the second transparent conducting patterns of each of the second transparent conducting pattern groups is connected to the driving circuit die of each of the front pixel areas, and another end of each of the second transparent conducting patterns of each of the second transparent conducting pattern groups is connected to each of the electrode pads of the electrode pad groups of each of the front pixel areas. In the cutting step, the integrated circuit wafer is cut to separate the front pixel areas into the light emitting diode pixel packages.

### BRIEF DESCRIPTION OF THE DRAWINGS

The present disclosure can be more fully understood by reading the following detailed description of the embodiment, with reference made to the accompanying drawings as follows:

FIG. 1 shows a front view of a light emitting diode pixel package according to one embodiment of the present disclosure.

FIG. 2 shows a cross-sectional view of the light emitting diode pixel package according to the embodiment of FIG. 1.

FIG. 3 shows a block flow diagram of a manufacturing method of light emitting diode pixel packages according to another embodiment of the present disclosure.

FIG. 4 shows a manufacturing flow schematic view of the manufacturing method according to the embodiment of FIG. 3.

FIG. 5 shows a cutting schematic view of the manufacturing method according to the embodiment of FIG. 3.

### DETAILED DESCRIPTION

The embodiments of the present disclosure will be illustrated with drawings hereinafter. In order to clearly describe the content, many practical details will be mentioned with the description hereinafter. However, it will be understood by the reader that the practical details will not limit the present disclosure. In other words, in some embodiment of the present disclosure, the practical details are not necessary. Additionally, in order to simplify the drawings, some conventional structures and elements will be illustrated in the drawings in a simple way; the repeated elements may be labeled by the same or similar reference numerals.

In addition, the terms first, second, third, etc. are used herein to describe various elements or components, these elements or components should not be limited by these terms. Consequently, a first element or component discussed below could be termed a second element or component. Moreover, the combinations of the elements, the components, the mechanisms and the modules are not well-known, ordinary or conventional combinations, and whether the combinations can be easily completed by the one skilled in the art cannot be judged based on whether the elements, the components, the mechanisms or the module themselves are well-known, ordinary or conventional.

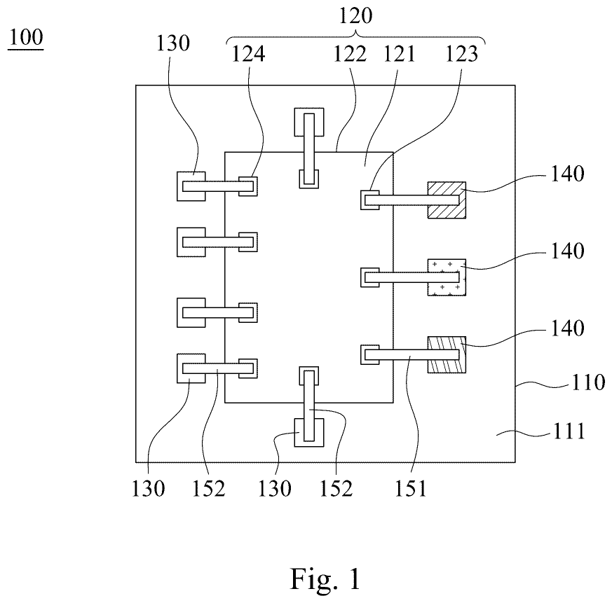

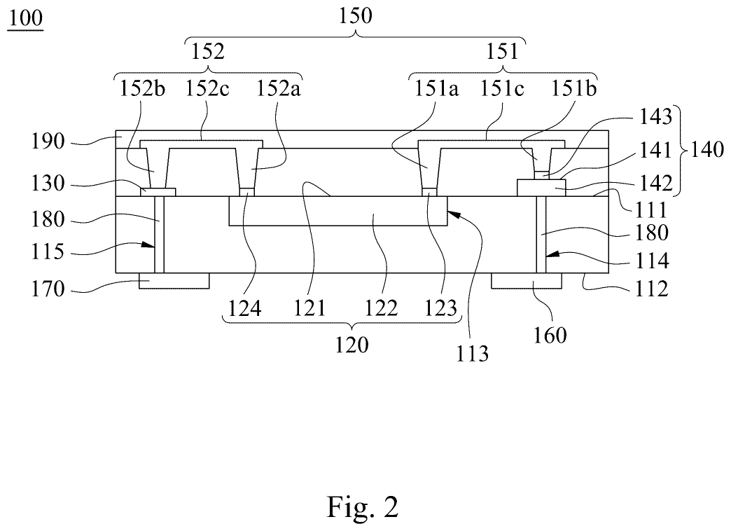

FIG. 1 shows a front view of a light emitting diode pixel package 100 according to one embodiment of the present disclosure. FIG. 2 shows a cross-sectional view of the light emitting diode pixel package 100 according to the embodiment of FIG. 1. It is noted that, in order to clearly clarify the drawings, the cross-sectional view of the drawings is show without section lines. The light emitting diode pixel package 100 includes a substrate 110, a driving circuit die 120, a plurality of LED dice 140, a plurality of electrode pads 130 and a packaging glue layer 150.

The substrate 110 includes a front pixel area 111, a back pixel area 112 opposite to the front pixel area 111, and a recess 113 located at the front pixel area 111. The driving circuit die 120 is disposed at the recess 113 and includes a die top surface 121. The LED dice 140 are disposed at the front pixel area 111 periodically, each of the LED dice 140 includes a light emitting surface 141, and each of the light emitting surfaces 141 is higher than the die top surface 121. The electrode pads 130 are disposed at the front pixel area 111 periodically. The packaging glue layer 150 is disposed at the front pixel area 111 and includes a plurality of first transparent conducting patterns 151 and a plurality of second transparent conducting patterns 152. One end of each of the first transparent conducting patterns 151 is connected to the driving circuit die 120, and another end of each of the first transparent conducting patterns 151 is connected to each of the LED dice 140. One end of each of the second transparent conducting patterns 152 is connected to the driving circuit die 120, and another end of each of the second transparent conducting patterns 152 is connected to each of the electrode pads 130.

Therefore, with that the driving circuit die 120 is disposed in the recess 113 and the light emitting surface 141 of each of the LED dice 140 is higher than the die top surface 121, the light of the LED dice 140 is prevented from being blocked. In addition, with that the packaging glue layer 150 includes the first transparent conducting patterns 151 and the second transparent conducting patterns 152, the thickness of the light emitting diode pixel package 100 is decreased.

In the embodiment shown in FIGS. 1 and 2. The substrate 110 may be made by a transparent material and is rectangular board-shaped. The substrate 110 may include the recess 113 whose size matches the size of the driving circuit die 120, and thus the driving circuit die 120 may be placed in the recess 113. The electrode pads 130 may be disposed at the substrate 110 in a conventional way, and the details thereof are not a key factor of the present disclosure and will not be described.

The driving circuit die 120 is an integrated circuit that is not packaged. The driving circuit die 120 may include a die body 122 and a plurality of foot pads 123, 124. The die top surface 121 indicates an upper surface of the die body 122, and the foot pads 123, 124 may be disposed at the die top surface 121 periodically. As the driving circuit die 120 is placed in the recess 113, the die top surface 121 may be aligned with a pixel surface of the front pixel area 111, and therefore the foot pads 123, 124 may be higher than the pixel surface. A number of the foot pads 123 is equal to a number of the LED dice 140, and the foot pads 123 are used to be electrically connected to the LED dice 140. The foot pads 124 may be used for a power positive pole, a power negative pole, a major displaying data output, a major displaying data input, a minor displaying data output, and a minor displaying data input, but the present disclosure is not limited thereto.

A number of the LED dice 140 may be three, and the three LED dice 140 emit different light colors, e.g., red, blue and yellow. Each of the LED dice 140 may have a vertical LED die structure and includes an LED body 142 and a die top electrode 143 disposed at the LED body. A die substrate (not shown) of the LED body 142 may be made of a metal and can be served as a die bottom electrode. Hence, the LED body 142 may be directly welded at the front pixel area 111 of the substrate. In other embodiments, an extra die bottom electrode may be disposed at a bottom of the LED body of the LED die for welding the LED die on the front pixel area, but the present disclosure is not limited thereto.

The light emitting diode pixel package 100 may further include a plurality of driving circuit pads 170, a plurality of LED die pads 160 and a plurality of conducting portions 180. Each of the driving circuit pads 170 and each of the LED die pads 160 are disposed at the back pixel area 112 periodically. The substrate 110 may further include a plurality of first through holes 114 and a plurality of second through holes 115. Each of the first through holes 114 penetrates the substrate 110 and is connected to each of the LED die pads 160 and each of the LED dice 140. Each of the second through holes 115 penetrates the substrate 110 and is connected to each of the driving circuit pads 170 and each of the electrode pads 130, and the conducting portions 180 are respectively filled in the first through holes 114 and the second through holes 115.

Precisely, the first through holes 114 and the second through holes 115 are formed during manufacturing the substrate 110. Since the first through holes 114 and the second through holes 114 penetrate the substrate 110, electric connection may be formed after the conducting portions 180 are filled, thereby electrically connecting the elements at the front pixel area 111 and the back pixel area 112. Hence, the LED die pads 160 may be electrically connected to the LED dice 140, and the driving circuit pads 170 are electrically connected to the driving circuit die 120. Consequently, the light emitting diode pixel package 100 may be electrically connected to other elements via the driving circuit pads 170 and the LED die pads 160.

As forming the packaging glue layer 150, a packaging glue may be coated on the front pixel area 111, and a plurality of grooves may be formed by a photolithography process to correspond to the electrode pads 130, the foot pads 123, 124 and the die top electrode 143. After which, the first transparent conducting patterns 151 and the second transparent conducting patterns 152 may be formed. In the embodiment of FIGS. 1 and 2, a transparent conducting glue, e.g., an indium tin oxide, may be filled in the grooves to form the first transparent conducting patterns 151 and the second transparent conducting patterns 152. That is to say, each of the first transparent conducting patterns 151 and the second transparent conducting patterns 152 is the indium tin oxide, and blocking of the light may be prevented.

During manufacturing, the transparent conducting glue may be coated on the packaging glue and flows into the grooves. After which, the photolithography process is used to remove unnecessary parts, thereby allowing each of the first transparent conducting patterns 151 to include two first connecting segments 151a, 151b and one first central segment 151c and to allow each of the second transparent conducting patterns 152 to include two second connecting segments 152a, 152b and one second central segment 152c. The first connecting segments 151a, 151b are respectively connected to the foot pad 123 and the die top electrode 143, and the first central segment 151c is connected between the first connecting segments 151a, 151b. The second connecting segments 152a, 152b are respectively connected to the foot pad 124 and the electrode pad 130, the second central segment 152c is connected between the second connecting segments 152a, 152b, and the electrical connection is completed.

The light emitting diode pixel package 100 may further include a protecting layer 190 covering the packaging glue layer 150. Therefore, an effect for protecting the first transparent conducting patterns 151 and the second transparent conducting patterns 152 are achieved.

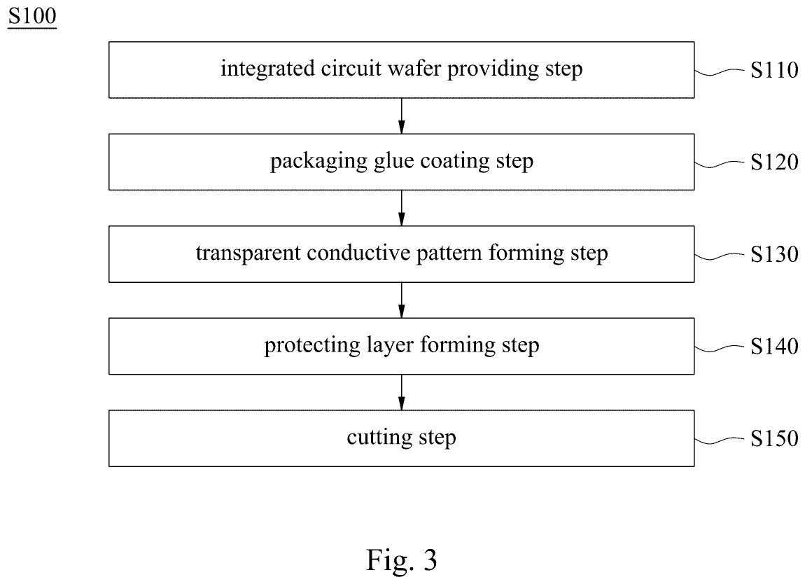

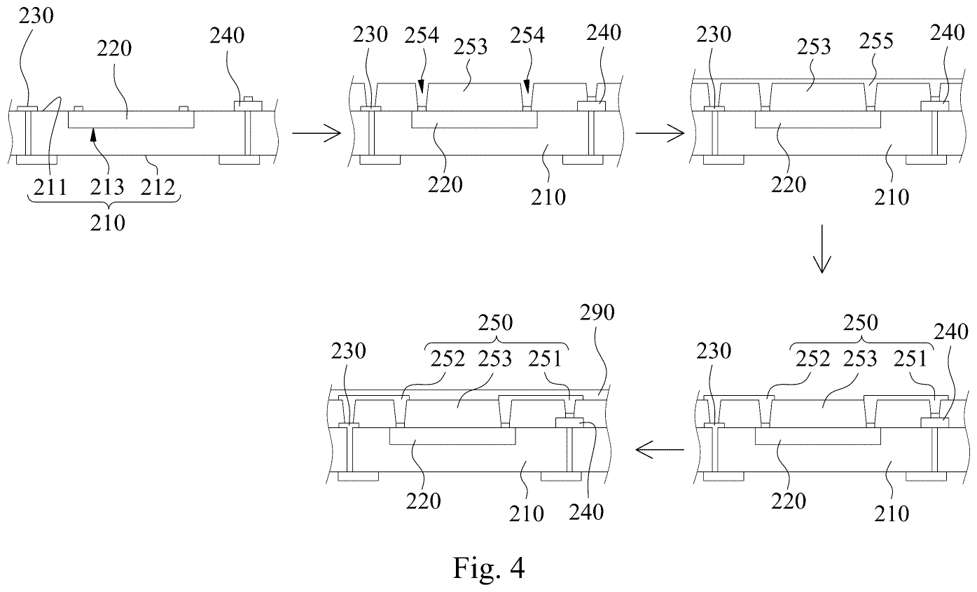

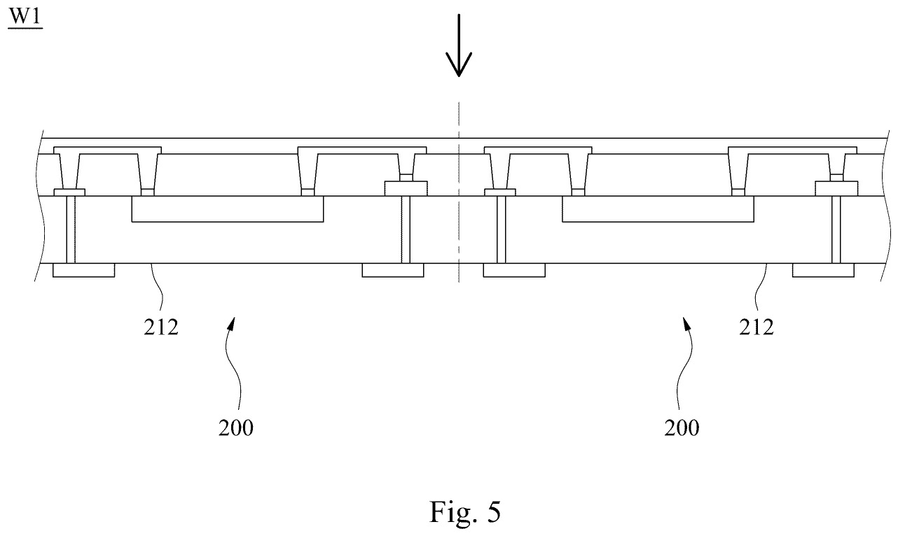

FIG. 3 shows a block flow diagram of a manufacturing method S100 of light emitting diode pixel packages 200 according to another embodiment of the present disclosure. FIG. 4 shows a manufacturing flow schematic view of the manufacturing method S100 according to the embodiment of FIG. 3. FIG. 5 shows a cutting schematic view of the manufacturing method S100 according to the embodiment of FIG. 3. The manufacturing method S100 includes an integrated circuit wafer providing step S110, a packaging glue coating step S120, a transparent conductive pattern forming step S130 and a cutting step S150.

In the integrated circuit wafer providing step S110, an integrated circuit wafer W1 is provided. The integrated circuit wafer W1 includes a substrate 210, a plurality of driving circuit dice 220, a plurality of LED die groups and a plurality of electrode pad groups. The substrate 210 includes a plurality of front pixel areas 211 and a plurality of recesses 213. Each of the recesses 213 is located at each of the front pixel areas 211. Each of the driving circuit dice 220 is disposed at each of the recesses 213 and includes a die top surface (not labeled in FIGS. 3 to 5). Each of the LED die groups is located at each of the front pixel areas 211. Each of the LED die groups includes a plurality of LED dice 240 arranged periodically, and each of the LED dice 240 includes a light emitting surface (not labeled in FIGS. 3 to 5). Each of the light emitting surfaces is higher than each of the die top surfaces, and each of the electrode pad groups is located at each of the front pixel areas 111.

In the packaging glue coating step S120, a packaging glue 253 is coated on the front pixel areas 211 of the substrate 210 to cover the driving circuit dice 220, the LED die groups and the electrode pad groups.

In the transparent conductive pattern forming step S130, a plurality of grooves 254 are formed on the packaging glue 253, and a transparent conducting glue 255 is covered thereon. The transparent conducting glue 255 flows into the grooves 254 to form a plurality of first transparent conducting pattern groups and a plurality of second transparent conducting pattern groups, and the first transparent conducting pattern groups, the second transparent conducting pattern groups and the transparent conducting glue 255 forms a packaging glue layer 250. Each of the first transparent conducting pattern groups corresponds to each of the front pixel areas 211 and includes a plurality of first transparent conducting patterns 251, one end of each of the first transparent conducting patterns 251 of each of the first transparent conducting pattern groups is connected to the driving circuit die 220 of each of the front pixel areas 211, and another end of each of the first transparent conducting patterns 251 of each of the first transparent conducting pattern groups is connected to each of the LED dice 240 of each of the front pixel areas 211. Each of the second transparent conducting pattern groups corresponds to each of the front pixel areas 211 and includes a plurality of second transparent conducting patterns 252, one end of each of the second transparent conducting patterns 252 of each of the second transparent conducting pattern groups is connected to the driving circuit die 220 of each of the front pixel areas 211, and another end of each of the second transparent conducting patterns 252 of each of the second transparent conducting pattern groups is connected to each of the electrode pads 230 of each of the electrode pad groups of each of the front pixel areas 211.

In the cutting step S150, the integrated circuit wafer is cut to separate the front pixel areas 211 into the light emitting diode pixel packages 200.

Moreover, the manufacturing method S100 may further include a protecting layer forming step S140 being exerted before the cutting step S150, and the protecting layer forming step S140 is to form a protecting layer 290 covering the packaging glue layer 250.

As shown in FIGS. 3 and 4, in the integrated circuit wafer W1 providing step S110, the elements other than the packaging glue layer 250 and the protecting layer 290 are welded, and the driving circuit dice 220 and the LED die groups are connected. The photolithography process may be later used to form the packaging glue layer 250. Hence, the integrated circuit wafer W1 may further include a plurality of driving circuit pad groups, a plurality of LED die pad groups and a plurality of conducting portions (not labeled in FIGS. 3 and 5). The substrate 210 may further include a plurality of back pixel areas 212, and each of the back pixel areas 212 is opposite to each of the front pixel areas 211. A plurality of driving circuit pads of each of the driving circuit pad groups and a plurality of LED die pads of each of the LED die pad groups are disposed at each of the back pixel areas 212 periodically. The substrate 210 may further include a plurality of first through hole groups and a plurality of second through hole groups. Each of the first through hole groups includes a plurality of first through holes (not labeled in FIGS. 3 and 5). Each of the first through holes penetrates the substrate 210 and is connected to each of the LED die pads (not labeled in FIGS. 3 and 5) and each of the LED dice 240. Each of the second through hole groups includes a plurality of second through holes (not labeled in FIGS. 3 and 5). Each of the second through holes penetrates the substrate 210 and is connected to each of the driving circuit pads (not labeled in FIGS. 3 and 5) and each of the electrode pads 230. The conducting portions are respectively filled in the first through holes and the second through holes.

In the packaging glue coating step S120, the packaging glue 253 are coated. After which, processes including exposure, development and etching are used to form the grooves on each of the front pixel area 211 to connect the LED dice 240, the driving circuit die 220 and the electrode pads 230. In the transparent conducting pattern forming step S130, the transparent conducting glue 255 may flow into and fill the grooves 254 to form a transparent conducting film on the surface of the packaging glue 253. After which, parts of the transparent conducting film may be etched to remove the unnecessary electrical connection to form the first transparent conducting patterns 251 and the second transparent conducting patterns 252. Finally, the protecting layer 290 may be formed thereon.

After finishing the above steps, the integrated circuit wafer W1 may be cut in the cutting step S150. Therefore, the connected back pixel areas 212 and the front pixel areas 211 as well are separated from each other, thereby forming the light emitting diode pixel packages 200.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A light emitting diode pixel package, comprising:
a substrate, comprising:
a front pixel area;
a back pixel area opposite to the front pixel area; and
a recess located at the front pixel area;
a driving circuit die disposed at the recess and comprising a die top surface;
a plurality of LED dice disposed at the front pixel area periodically, each of the LED dice comprising a light emitting surface, wherein each of the light emitting surfaces is higher than the die top surface;
a plurality of electrode pads disposed at the front pixel area periodically; and
a packaging glue layer disposed at the front pixel area and comprising:
a plurality of first transparent conducting patterns, wherein one end of each of the first transparent conducting patterns is connected to the driving circuit die, and another end of each of the first transparent conducting patterns is connected to each of the LED dice; and
a plurality of second transparent conducting patterns, wherein one end of each of the second transparent conducting patterns is connected to the driving circuit die, and another end of each of the second transparent conducting patterns is connected to each of the electrode pads.

2. The light emitting diode pixel package of claim 1, further comprising a plurality of driving circuit pads, a plurality of LED die pads and a plurality of conducting portions, each of the driving circuit pads and each of the LED die pads are disposed at the back pixel area periodically, the substrate further comprises a plurality of first through holes and a plurality of second through holes, each of the first through holes penetrates the substrate and is connected to each of the LED die pads and each of the LED dice, each of the second through holes penetrates the substrate and is connected to each of the driving circuit pads and each of the electrode pads, and the conducting portions are respectively filled in the first through holes and the second through holes.

3. The light emitting diode pixel package of claim 1, further comprising a protecting layer covering the packaging glue layer.

4. The light emitting diode pixel package of claim 1, wherein the substrate is made of a transparent material.

5. The light emitting diode pixel package of claim 1, wherein each of the first transparent conducting patterns and the second transparent conducting patterns is an indium tin oxide.

6. The light emitting diode pixel package of claim 1, wherein the die top surface is aligned with a pixel surface of the front pixel area.

7. The light emitting diode pixel package of claim 6, wherein the driving circuit die comprises a die body and a plurality of foot pads, the foot pads are disposed at the die top surface periodically, and the foot pads are higher than the pixel surface.

8. The light emitting diode pixel package of claim 1, wherein each of the LED dice has a vertical LED die structure and comprises an LED body and a die top electrode disposed at the LED body.

9. A manufacturing method for light emitting diode pixel packages, comprising:
an integrated circuit wafer providing step, wherein an integrated circuit wafer is provided, the integrated circuit wafer comprises a substrate, a plurality of driving circuit dice, a plurality of LED die groups and a plurality of electrode pad groups, the substrate comprises a plurality of front pixel areas and a plurality of recesses, each of the recesses is located at each of the front pixel areas, each of the driving circuit dice is disposed at each of the recesses and comprises a die top surface, each of the LED die groups is located at each of the front pixel areas, each of the LED die groups comprises a plurality of LED dice arranged periodically, each of the LED dice comprises a light emitting surface, each of the light emitting surfaces is higher than each of the die top surfaces, and each of the electrode pad groups is located at each of the front pixel areas;
a packaging glue coating step, wherein a packaging glue is coated on the front pixel areas of the substrate to cover the driving circuit dice, the LED die groups and the electrode pad groups;
a transparent conductive pattern forming step, wherein a plurality of grooves are formed on the packaging glue, a transparent conducting glue is covered thereon, the transparent conducting glue flows into the grooves to form a plurality of first transparent conducting pattern groups and a plurality of second transparent conducting pattern groups, the first transparent conducting pattern groups, the second transparent conducting pattern groups and the transparent conducting glue forms a packaging glue layer, each of the first transparent conducting pattern groups corresponds to each of the front pixel areas and comprises a plurality of first transparent conducting patterns, one end of each of the first transparent conducting patterns of each of the first transparent conducting pattern groups is connected to the driving circuit die of each of the front pixel areas, another end of each of the first transparent conducting patterns of each of the first transparent conducting pattern groups is connected to each of the LED dice of each of the front pixel areas, each of the second transparent conducting pattern groups corresponds to each of the front pixel areas and comprises a plurality of second transparent conducting patterns, one end of each of the second transparent conducting patterns of each of the second transparent conducting pattern groups is connected to the driving circuit die of each of the front pixel areas, and another end of each of the second transparent conducting patterns of each of the second transparent conducting pattern groups is connected to each of the electrode pads of the electrode pad groups of each of the front pixel areas; and
a cutting step, wherein the integrated circuit wafer is cut to separate the front pixel areas into the light emitting diode pixel packages.

10. The manufacturing method of claim 9, further comprising a protecting layer forming step being exerted before the cutting step, wherein the protecting layer forming step is to form a protecting layer covering the packaging glue layer.

11. The manufacturing method of claim 9, wherein the substrate is made of a transparent material.

12. The manufacturing method of claim 9, wherein each of the first transparent conducting patterns and the second transparent conducting patterns is an indium tin oxide.

13. The manufacturing method of claim 9, wherein the integrated circuit wafer further comprises a plurality of driving circuit pad groups, a plurality of LED die pad groups and a plurality of conducting portions, the substrate further comprises a plurality of back pixel areas, each of the back pixel areas is opposite to each of the front pixel areas, a plurality of driving circuit pads of each of the driving circuit pad groups and a plurality of LED die pads of each of the LED die pad groups are disposed at each of the back pixel areas periodically, the substrate further comprises a plurality of first through hole groups and a plurality of second through hole groups, each of the first through hole groups comprises a plurality of first through holes, each of the first through holes penetrates the substrate and is connected to each of the LED die pads and each of the LED dice, each of the second through hole groups comprises a plurality of second through holes, each of the second through holes penetrates the substrate and is connected to each of the driving circuit pads and each of the electrode pads, and the conducting portions are respectively filled in the first through holes and the second through holes.

14. The manufacturing method of claim 9, wherein the grooves are formed by a photolithography process.
